(19) United States
(12) Patent Application Publication
(10) Pub. No.: US 2024/0288764 A1
(43) Pub. Date: Aug. 29, 2024

(54) DETERMINING LOCALIZED IMAGE PREDICTION ERRORS TO IMPROVE A MACHINE LEARNING MODEL IN PREDICTING AN IMAGE

(71) Applicant: ASML NETHERLANDS B.V., Veldhoven (NL)

(72) Inventor: Ayman HAMOUDA, Milpitas, CA (US)

(73) Assignee: ASML NETHERLANDS B.V., Veldhoven (NL)

(21) Appl. No.: 18/570,572

(22) PCT Filed: Jun. 12, 2022
(86) PCT No.: PCT/EP2022/065924

§ 371 Date: Dec. 14, 2023

Related U.S. Application Data
(60) Provisional application No. 63/218,705, filed on Jul. 6, 2021.

(51) Int. Cl. G03F 1/36; G03F 7/00; G06N 20/00

(52) U.S. Cl. CPC G03F 1/36; G03F 7/70441; G03F 7/705; G03F 7/70508; G06N 20/00

(57) ABSTRACT

Identification of error clusters in an image predicted by a simulation model (e.g., a machine learning model), and training or adjusting the simulation model by feeding the error cluster information back to the simulation model to improve the prediction in regions of the image having the error clusters. Further, embodiments are disclosed for scoring the predicted images, or the simulation models generating those predicted images, based on a severity of errors in the error clusters. The score may be used in evaluating the simulation models to select a specific simulation model for generating a predicted image that may be used in manufacturing a mask to print a desired pattern on a substrate.

### CROSS-REFERENCE TO RELATED APPLICATIONS

This application claims priority of U.S. application No. 63/218,705 which was filed on Jul. 6, 2021 and which is incorporated herein in its entirety by reference.

### TECHNICAL FIELD

The description herein relates to lithographic apparatuses and processes, and more particularly to determining errors in images predicted using machine learning.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g., comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a wafer stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, microlithography is a central step in the manufacturing of ICs, where patterns formed on substrates define functional elements of the ICs, such as microprocessors, memory chips etc. Similar lithographic techniques are also used in the formation of flat panel displays, micro-electromechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC) in the design layout, or other methods generally defined as “resolution enhancement techniques” (RET).

### SUMMARY

In some embodiments, there is provided a non-transitory computer-readable medium having instructions that, when executed by a computer, cause the computer to execute a method for determining error clusters in a predicted pattern representation and using location information of the error clusters as an input for training a machine learning model to generate an adjusted predicted pattern representation for use in printing a target pattern on a substrate. The method includes: obtaining, using a first machine learning model, a first predicted pattern representation associated with a target pattern to be printed on a substrate; obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and training, based on location information of the first plurality of error clusters, the first machine learning model to generate an adjusted predicted pattern representation.

In some embodiments, there is provided a non-transitory computer readable medium having instructions that, when executed by a computer, cause the computer to execute a method for determining error clusters in a predicted pattern representation and using location information of the error clusters. The method includes: obtaining, using a machine learning model, a first predicted pattern representation associated with a target pattern to be printed on a substrate; obtaining a prediction error map from the first predicted pattern representation, the prediction error map indicative of a plurality of errors in the first predicted pattern representation compared to a reference pattern representation; obtaining cluster error data from the prediction error map, wherein the cluster error data is indicative of a first plurality of error clusters, the first plurality of error clusters including a first error cluster that is indicative of a collection of errors in a specified region in the first predicted pattern representation; and generating for display, on a user interface, the cluster error data.

In some embodiments, there is provided a non-transitory computer readable medium having instructions that, when executed by a computer, cause the computer to execute a method for selecting a machine learning model among a plurality of machine learning models for generating a predicted image to be used in printing a target pattern on a substrate. The method includes: obtaining, using a plurality of machine learning models, a plurality of predicted images associated with a target pattern to be printed on a substrate, wherein the predicted images include a first predicted image generated using a first machine learning model of the plurality of machine learning models; obtaining a plurality of scores associated with the predicted images, the plurality of scores including a first score associated with the first predicted image, wherein the first score is determined based on a first plurality of prediction errors in the first predicted image; evaluating the machine learning models based on the scores; and selecting the first machine learning model based on the first score satisfying a specified criterion.

In some embodiments, there is provided a method for determining error clusters in a predicted pattern representation and using location information of the error clusters as an input for training a machine learning model to generate an adjusted predicted pattern representation for use in printing a target pattern on a substrate. The method includes: obtaining, using a first machine learning model, a first predicted pattern representation associated with a target pattern to be printed on a substrate; obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and training, based on location information of the first plurality of error clusters, the first machine learning model to generate an adjusted predicted pattern representation.

In some embodiments, there is provided a method for determining error clusters in a predicted pattern representation and using location information of the error clusters. The method includes: obtaining, using a machine learning model, a first predicted pattern representation associated with a target pattern to be printed on a substrate; obtaining a prediction error map from the first predicted pattern representation, the prediction error map indicative of a plurality of errors in the first predicted pattern representation compared to a reference pattern representation; obtaining cluster error data from the prediction error map, wherein the cluster error data is indicative of a first plurality of error clusters, the first plurality of error clusters including a first error cluster that is indicative of a collection of errors in a specified region in the first predicted pattern representation; and generating for display, on a user interface, the cluster error data.

In some embodiments, there is provided a method for selecting a machine learning model among a plurality of machine learning models for generating a predicted image to be used in printing a target pattern on a substrate. The method includes: obtaining, using a plurality of machine learning models, a plurality of predicted images associated with a target pattern to be printed on a substrate, wherein the predicted images include a first predicted image generated using a first machine learning model of the plurality of machine learning models; obtaining a plurality of scores associated with the predicted images, the plurality of scores including a first score associated with the first predicted image, wherein the first score is determined based on a first plurality of prediction errors in the first predicted image; evaluating the machine learning models based on the scores; and selecting the first machine learning model based on the first score satisfying a specified criterion.

In some embodiments, there is provided an apparatus for determining error clusters in a predicted pattern representation and using location information of the error clusters as an input for training a machine learning model to generate an adjusted predicted pattern representation for use in printing a target pattern on a substrate. The apparatus includes: a memory storing a set of instructions; and a processor configured to execute the set of instructions to cause the apparatus to perform a method, which includes: obtaining, using a first machine learning model, a first predicted pattern representation associated with a target pattern to be printed on a substrate; obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and training, based on location information of the first plurality of error clusters, the first machine learning model to generate an adjusted predicted pattern representation.

In some embodiments, there is provided an apparatus for determining error clusters in a predicted pattern representation and using location information of the error clusters. The apparatus includes: a memory storing a set of instructions; and a processor configured to execute the set of instructions to cause the apparatus to perform a method, which includes: obtaining, using a machine learning model, a first predicted pattern representation associated with a target pattern to be printed on a substrate; obtaining a prediction error map from the first predicted pattern representation, the prediction error map indicative of a plurality of errors in the first predicted pattern representation compared to a reference pattern representation; obtaining cluster error data from the prediction error map, wherein the cluster error data is indicative of a first plurality of error clusters, the first plurality of error clusters including a first error cluster that is indicative of a collection of errors in a specified region in the first predicted pattern representation; and generating for display, on a user interface, the cluster error data.

In some embodiments, there is provided an apparatus for selecting a machine learning model among a plurality of machine learning models for generating a predicted image to be used in printing a target pattern on a substrate. The apparatus includes: a memory storing a set of instructions; and a processor configured to execute the set of instructions to cause the apparatus to perform a method, which includes: obtaining, using a plurality of machine learning models, a plurality of predicted images associated with a target pattern to be printed on a substrate, wherein the predicted images include a first predicted image generated using a first machine learning model of the plurality of machine learning models; obtaining a plurality of scores associated with the predicted images, the plurality of scores including a first score associated with the first predicted image, wherein the first score is determined based on a first plurality of prediction errors in the first predicted image; evaluating the machine learning models based on the scores; and selecting the first machine learning model based on the first score satisfying a specified criterion.

### BRIEF DESCRIPTION OF THE DRAWINGS

FIG. 1 shows a block diagram of various subsystems of a lithography system.

FIG. 2 shows a flow for a patterning simulation method, according to an embodiment.

FIG. 3 is a block diagram of a system illustrating generation of predicted images by various simulation models, in accordance with one or more embodiments.

FIG. 4 is a block diagram of a system for scoring a predicted image, in accordance with one or more embodiments.

FIG. 5 is a flow diagram of a method for scoring a predicted image, in accordance with one or more embodiments.

FIG. 6 is a block diagram of a scoring component for adjusting a score of an error cluster, in accordance with one or more embodiments.

FIG. 7 is a block diagram of a system for training a machine learning (ML) model to generate a predicted image based on an error cluster map, in accordance with one or more embodiments.

FIG. 8 is a flow chart of a process of training a simulation model to generate a predicted image based on an error cluster map, in accordance with one or more embodiments.

FIG. 9 is a block diagram of an example computer system, in accordance with one or more embodiments.

### DETAILED DESCRIPTION

In lithography, a patterning device (e.g., a mask) may provide a mask pattern (e.g., mask design layout) corresponding to a target pattern (e.g., target design layout), and this mask pattern may be transferred onto a substrate by transmitting light through the mask pattern. Machine learning (ML) models may be used to predict various intermediate patterns for a given target pattern that may be used in generating the mask pattern to obtain the desired pattern on the substrate. For example, different ML models may be employed to predict these intermediate images. The ML models may be evaluated based on the accuracy of the predicted images to select a ML model that generates the most accurate predicted image. Typically, the accuracy of a predicted image or any representation thereof is determined using a metric such as root mean square error (“RMSE”), which is determined based on pixel-to-pixel difference between the predicted image and the reference image. The ML models may be evaluated based on the RMSE, and a ML model whose predicted image has the lowest RMSE may be chosen as the most accurate ML model. However, just using RMSE to evaluate images in the context of lithography has some drawbacks. In lithography, regions of poor prediction in an image may cause a significant deviation in contours of the predicted pattern from the target pattern, which may cause the printed pattern on the substrate to be significantly different from the target pattern. The RMSE metric, which indicates the error in the predicted image as a whole, does not aid in locating regions with poor predictions. Another way to characterize prediction error is using a pixel error map (e.g., a map or an image showing difference between every pixel of the predicted image and the reference image), which may not capture regions of poor prediction.

The present disclosure provides a mechanism of localizing and/or prioritizing prediction cluster errors in a pattern area. The model prediction of the pattern area may be a pixel image, contours, or any other representation of the pattern area that is well known in the art. In some embodiments, a representation predicted by a simulation model is analyzed to generate cluster error data which can be indicative of regional or block-wise error characteristics. In some embodiments, the cluster error data is generated by transforming, e.g., averaging smoothening, blurring, convoluting or low-pass filtering, an error map of a pattern representation. The cluster error data may be represented in an error cluster map that can directly indicate distribution of errors in clusters. The cluster error data may provide locations of error clusters in the pattern area. The simulation model can be a physical model, empirical or semi-empirical model, a ML model or any combination or hybrid thereof. In some embodiments, a predicted image is analyzed to locate regions having error clusters. For example, an error cluster is a collection of errors satisfying a threshold value in a region of the predicted image, where the threshold value may be related to error values, the region size, and/or any other suitable parameter. An error cluster map can be generated and used to identify error clusters in the predicted image.

The cluster error data may be used for any suitable purposes without departing from the scope of the present disclosure. For example, an error cluster map may provide a visual to a user the region or location of the image having an error cluster. In another example, the error cluster map may be used in an active learning process of a simulation model (e.g., an ML model) in which the error cluster map is fed back to the simulation model to adjust or train the simulation model to improve the prediction in the regions having significant error clusters. Further, the predicted images may be ranked based on the error clusters, which may be used in selecting a simulation model to generate a predicted image. For example, images of intermediate patterns predicted by a set of simulation models may be ranked and a specific simulation model may be chosen accordingly and used to generate images of intermediate patterns that may be used in generating a mask pattern to obtain the desired pattern on the substrate.

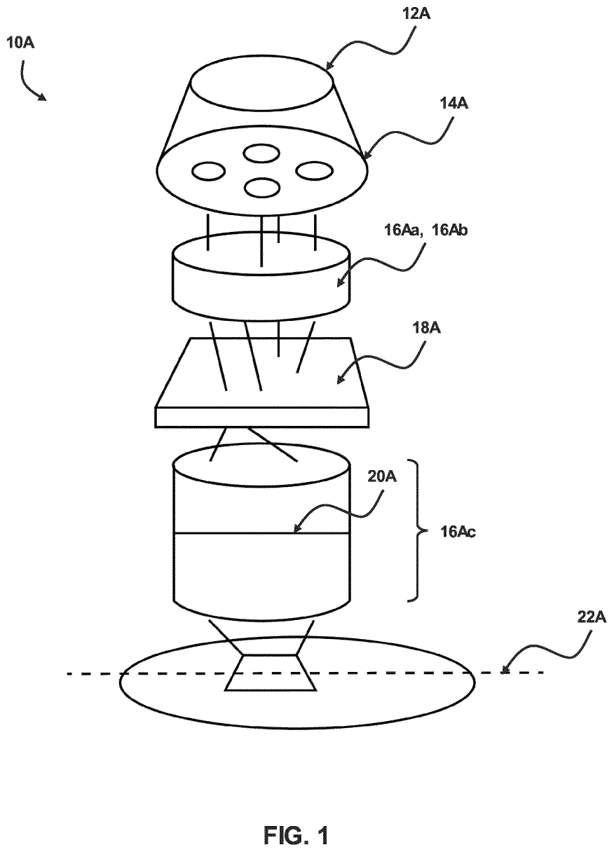

FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e., radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat. No. 5,229,872, which is incorporated herein by reference.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

Variables of a patterning process are called “processing variables.” The patterning process may include processes upstream and downstream to the actual transfer of the pattern in a lithography apparatus. A first category may be variables of the lithography apparatus or any other apparatuses used in the lithography process. Examples of this category include variables of the illumination, projection system, substrate stage, etc. of a lithography apparatus. A second category may be variables of one or more procedures performed in the patterning process. Examples of this category include focus control or focus measurement, dose control or dose measurement, bandwidth, exposure duration, development temperature, chemical composition used in development, etc. A third category may be variables of the design layout and its implementation in, or using, a patterning device. Examples of this category may include shapes and/or locations of assist features, adjustments applied by a resolution enhancement technique (RET), CD of mask features, etc. A fourth category may be variables of the substrate. Examples include characteristics of structures under a resist layer, chemical composition and/or physical dimension of the resist layer, etc. A fifth category may be characteristics of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). A sixth category may be characteristics of processes upstream of, or downstream to, pattern transfer in a lithographic apparatus, such as spin coating, post-exposure bake (PEB), development, etching, deposition, doping and/or packaging.

As will be appreciated, many, if not all of these variables, will have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

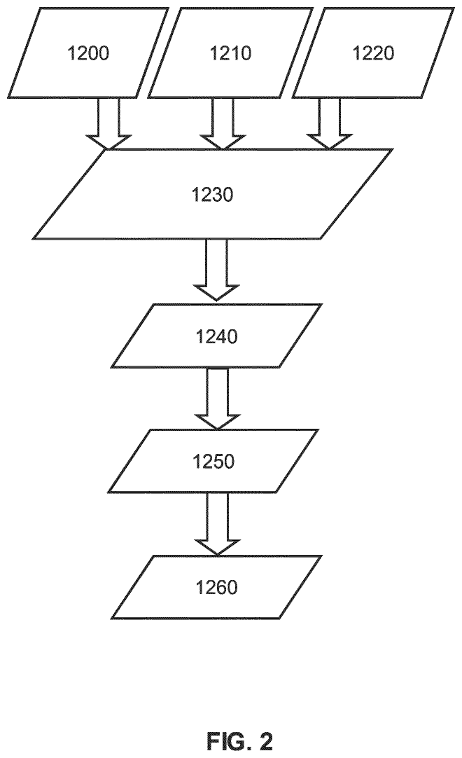

An exemplary flow chart for modelling and/or simulating parts of a patterning process is illustrated in FIG. 2. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (o) settings as well as any particular illumination shape (e.g., off-axis radiation shape such as annular, quadrupole, dipole, etc.), where σ (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model module 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 1230 can be simulated from the source model 1200, the projection optics model 1210 and the patterning device/design layout model module 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 1210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1260. The post-pattern transfer process model module 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

In the present disclosure, methods and systems are disclosed for generation of cluster error characteristics (e.g., an error cluster map) for a pattern representation predicted by a simulation model. The model can be adjusted or further trained based on the cluster error characteristics to improve the prediction in the regions of the image having significant error clusters. Further, methods and systems are disclosed for evaluating the predicted representations or the models based on the cluster error characteristics. For example, the cluster error data may be used in evaluating multiple models to select a specific model for generating a predicted image of an intermediate pattern that may be used in generating a mask pattern.

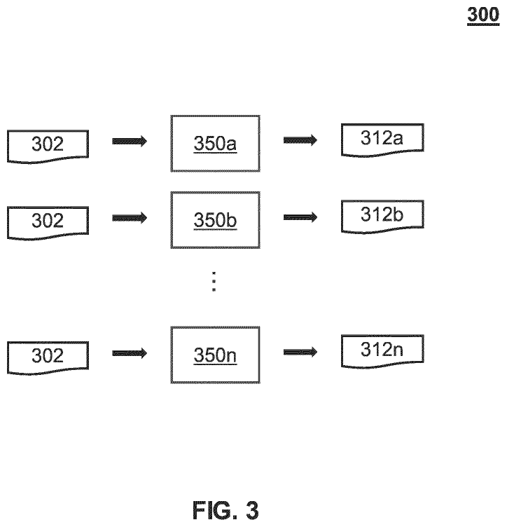

FIG. 3 is a block diagram of a system 300 illustrating generation of predicted images by various simulation models, in accordance with one or more embodiments. A simulation model may be used to generate an image based on an input image. For example, a simulation model 350a such as a ML model may be used to predict an image of an intermediate pattern (e.g., predicted image 312a) based on a target image 302 of a target pattern to be printed on a substrate. The target pattern includes target features that are to be printed on a substrate. In some embodiments, the intermediate pattern may include patterns corresponding to the target features and patterns corresponding to features other than the target features (e.g., sub-resolution assist features (SRAF)). The SRAFs are typically placed in the intermediate pattern near the target features to assist in printing the target features but are not themselves printed on the substrate. The predicted image 312a may be used to generate a mask pattern that may be used to print patterns corresponding to the target pattern on the substrate via a patterning or lithographic process. One example of a predicted image includes a continuous transmission mask (CTM) image that contains an intermediate pattern. CTM method is one of the methods for designing a mask pattern. The CTM method first designs a grayscale mask, referred to as a continuous transmission map, or CTM. The method involves optimization of grey scale values using a gradient descent, or other optimization methods so that a performance metric (e.g., edge placement error (EPE)) of a lithographic apparatus is improved. However, the CTM cannot be manufactured as a mask itself, since it is a grayscale mask with unmanufacturable features. The CTM may be optimized and then the optimized pattern may be used as a mask pattern. An example CTM optimization process is discussed in detail in U.S. patent publication 20170038692A1, which is incorporated herein in its entirety by reference, that describes different flows of optimization for lithographic processes. In some embodiments, target pattern data may be stored in a digital file format (e.g., GDSII or other formats), and the target image 302 may be rendered (e.g., using an image renderer) from the target pattern data.

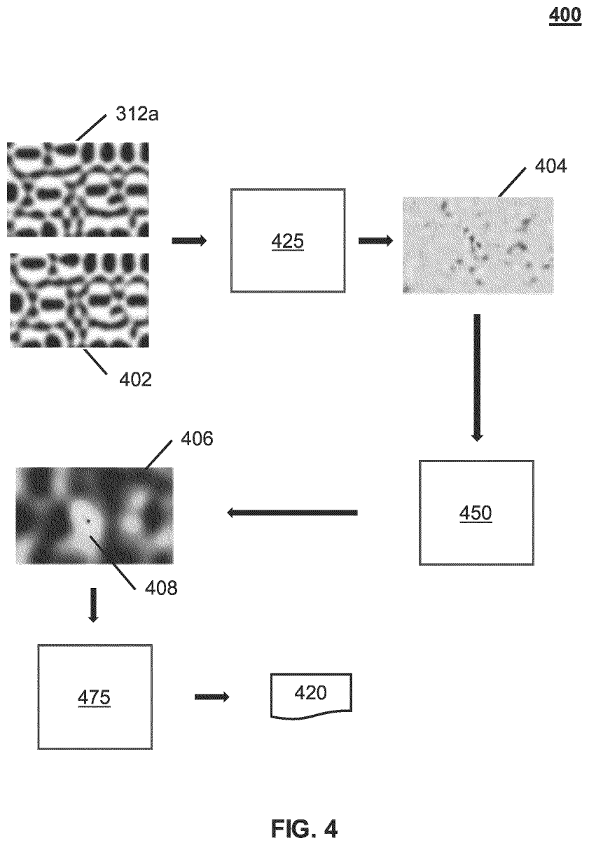

Different types of simulation models may be used to generate the predicted images from the target image 302. For example, simulation models 350a-350n may be used to generate the predicted images 312a-312n from the target image 302. A simulation model may include a ML model, e.g., a deep neural network ML model such as a convolutional neural network (CNN) model. The predicted images 312a-312n may not be the same as different simulation models may be trained differently and different predicted images 312a-312n may have different inaccuracies. Accordingly, the simulation models 350a-350n may have to be evaluated to choose a specific simulation model that may be used to generate a predicted image for generating a mask pattern. In some embodiments, the simulation models may be evaluated by determining the error clusters in the predicted images 312a-312n and scoring the predicted images 312a-312n based on one or more criteria related to degree or severity of the errors in the error clusters, as described at least with reference to FIGS. 4-6 below.

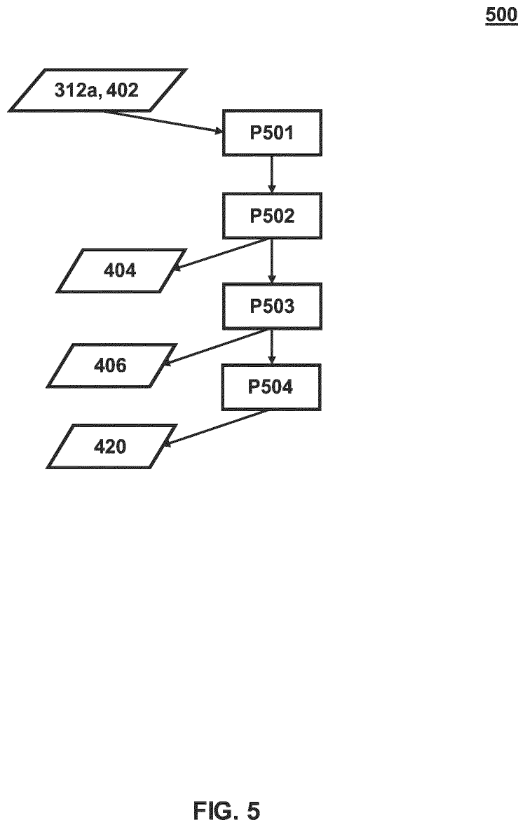

The following paragraphs describe selecting a predicted image or a model based on cluster error characteristics at least with reference to FIGS. 4 and 5. FIG. 4 is a block diagram of an exemplary system 400 for evaluating a predicted image, in accordance with one or more embodiments. FIG. 5 is a flow diagram of an exemplary method 500 for evaluating a predicted image, in accordance with one or more embodiments. In some embodiments, the method 500 may be implemented using the system 400. The system 400 may be configured to identify or locate an error cluster (e.g., a region having collection of errors satisfying a threshold value) in the prediction image, and to evaluate the predicted image (or the simulation model that generates the predicted image) based on a severity of errors in the error clusters. The system 400 includes a prediction error component 425, an error cluster component 450, and an evaluating component 475. At an operation P501, a predicted image 312a and a reference image 402 are obtained. In some embodiments, the predicted image 312a may be generated by a simulation model, such as the simulation model 350a, and may be an image of an intermediate pattern associated with a target pattern, as described at least with reference to FIG. 3. The reference image 402 may be an image of the intermediate pattern which is used to generate a mask pattern that when used in the patterning process produces patterns on the substrate in compliance with various constraints, guidelines and standards. The reference image 402 may be generated by one of the simulation models or using another process. Typically, the reference image 402 may have no error clusters or have error clusters associated with a score satisfying score criteria, e.g., a so-called ground truth image.

However, this discussion is merely exemplary. It will be appreciated that the present disclosure is not limited to any specific type of pattern representations based on which cluster error information is generated. Cluster error can be characterized for a suitable pattern representation based on any kind of reference. The pattern representations can be generated by using any suitable means without departing from the scope of the present disclosure. In some other embodiments, the pattern representation can be images obtained by using an inspection system, such as a scanning electron microscope.

Embodiments of the present disclosure are described in detail by reference to error cluster map. However, it will be appreciated that other characteristics or representation indicative of cluster error distribution can be used without departing from the scope of the present disclosure.

At operation P502, the predicted image 312a and the reference image 402 are provided as an input to the prediction error component 425 to generate a prediction error map 404. The prediction error map 404 may be indicative of errors in the predicted image 312a compared to the reference image 402. In some embodiments, the prediction error component 425 may generate the prediction error map 404 by comparing values of every pixel in the predicted image 312a with a corresponding pixel in the reference image 402 to determine the error between the pixels. That is, the prediction error map 404 may be a map of errors. An error may be indicative of a difference between a pixel in the predicted image 312a and the corresponding pixel in the reference image 402. The error may be quantified using an error value, which is determined as a difference between a value of a pixel in the predicted image 312a and a value of the corresponding pixel in the reference image 402.

At operation P503, the prediction error map 404 is processed by the error cluster component 450 to generate cluster error data, for example, an error cluster map 406. The error cluster map 406 may be indicative of error cluster distribution in the predicted image 312a. An error cluster can indicate a collection of errors in a specified region or location of the predicted image 312a that satisfy a threshold value. For example, the error cluster map 406 includes an error cluster 408. The error cluster map 406 may include one or more error clusters. The error cluster component 450 may generate the error cluster map 406 by deriving the error clusters from the prediction error map 404 in a number of ways. In some embodiments, the error cluster component 450 may perform a transformation operation (e.g., linear or non-linear transformation) on the prediction error map 404 to generate the error cluster map 406. The transformation can include averaging, smoothening blurring, convolution, low-pass filtering or clustering. For example, the error cluster component may perform a linear transformation, such as a convolution operation (e.g., Gaussian convolution or any other suitable convolution) or a filtering operation, to derive the error clusters from the prediction error map 404. The Gaussian convolution performed on the error values (e.g., values obtained from the prediction error map 404) may result in clustering errors in adjacent pixels. In some embodiments, the error cluster component 450 may derive the error clusters from the prediction error map 404 using other transformation methods (e.g., ML methods, k-Means clustering, KNN clustering, Gaussian mixture model, or other clustering method). In some embodiments, not all error clusters may have the same impact on the patterns printed on the substrate. Accordingly, the error clusters may be scored to determine their severity.

At operation P504, the evaluating component 475 determines an evaluation result, e.g., a score 420, for the predicted image 312a. In some embodiments, the score 420 of the predicted image 312a is a function of scores of the error clusters in the error cluster map 406. The evaluation result of an error cluster 408 may be determined in any suitable ways that are well known in the art. For example, the score of an error cluster 408 may be the sum of all error values in the error cluster 408. In another example, the score of an error cluster 408 may be an average of all error values in the error cluster 408. In some embodiments, the higher the score the more impact the error cluster may have on the patterning process. In some embodiments, not all error clusters may be scored as not all error clusters may have an impact on the pattering process. For example, error clusters having a local maxima below a specified threshold may not have a significant impact on the pattering process and therefore, may be excluded from scoring. In other words, error clusters having a local maxima equal to, or exceeding, the specified threshold may be identified for scoring and a location associated with the local maxima may be stored as the location data of the error clusters. In some embodiments, a local maximum of an error cluster 408 is determined for a portion of the error cluster map 406 that has the error cluster 408.

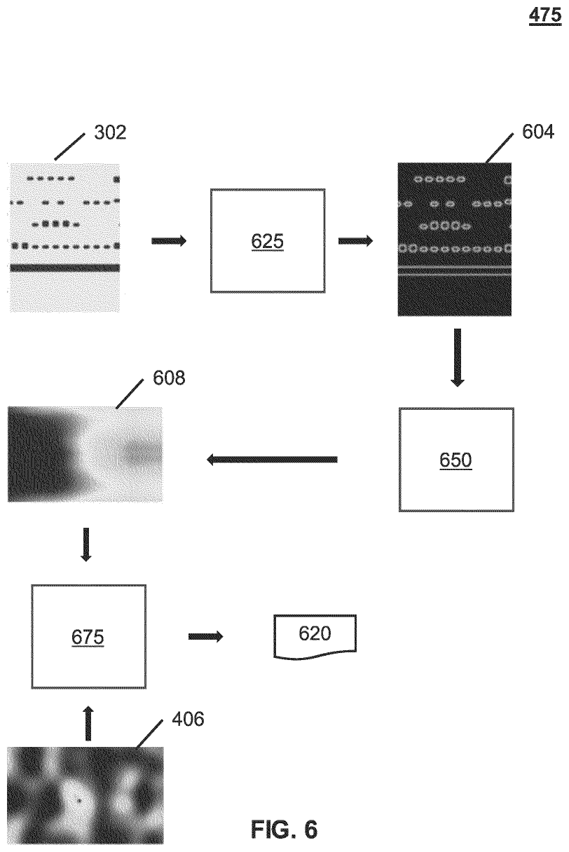

In some embodiments, the evaluation result of the error clusters may be adjusted based on various prescribed criteria. For example, the score of an error cluster nearer to a target feature may be weighted more than the score of an error cluster farther from the target feature because errors closer to the target feature may have a greater impact on the patterning process than the errors farther from the target feature. Accordingly, the predicted image 312a is analyzed to adjust the evaluation result of the error clusters based on their distance or proximity to the target features. Details of adjusting the evaluation result of an error cluster are described at least with reference to FIG. 6 below.

FIG. 6 is a block diagram of the evaluating component 475 for adjusting the evaluation result (e.g., score) of an error cluster, in accordance with one or more embodiments. The evaluating component 475 includes an edge extractor 625, a distance map component 650, and a weighting component 675. A target image, such as the target image 302, is input to the edge extractor 625 for extracting edges or contours of the target features in the target pattern. The target image 302 includes target features or main features to be printed on the substrate. The edge extractor 625 identifies the edges of the target features and generates an edge image 604 having the edges of the target features.

The edge image 604 is input to a distance map component 650 to generate a distance modulation map 608 in which map locations are weighted based on their distances from the target features. That is, locations closer to the target features (e.g., darker regions in the distance modulation map 608) are assigned greater weight than the locations farther from the target features (e.g., lighter regions in the distance modulation map 608). The error clusters closer to the target features may, therefore, be scored higher than the error clusters farther from the target features. Note that the distance modulation map 608 is illustrated for only a portion of the target pattern and not for all target features in the target pattern. The distance map component 650 may generate the distance modulation map in various ways. For example, the distance map component 650 may perform a transformation operation (e.g., a convolution operation such as a Gaussian convolution) on the edge image 604 to generate a distance modulation map, which may further be normalized to assign weights based on the impact of the distances of the error clusters to the target features.

The distance modulation map 608 and the error cluster map 406 are input to the weighting component 675 for adjusting the score of the error cluster 408 based on its proximity to the target features. For example, the weighting component 675 may generate an adjusted score 620 of the error cluster 408 by increasing the score the closer the error cluster 408 is to the target feature (e.g., overlaps with, or is closer to, the darker region in the distance modulation map 608), or decreasing the score the farther the error cluster 408 is from the target feature (e.g., overlaps with the lighter region in the distance modulation map 608). The weighting component 675 may determine the adjusted score 620 based on the error cluster map 406 and the distance modulation map 608 in various ways. For example, the weighting component 675 may perform a dot product operation between the distance modulation map 608 and the error cluster map 406 to determine the adjusted score 620.

While the foregoing description discusses adjusting the evaluation result of the error cluster 408 based on the proximity to the target features, the evaluation result may be adjusted based on other criteria. For example, the evaluation result may be adjusted based on the distance or proximity of the error cluster to a critical feature. In some embodiments, the error cluster being proximate to a critical target feature may have a greater impact on the patterning process than being proximate to other target features. In some embodiments, a critical feature includes a target feature that satisfies a specified criterion. For example, a target feature that has a mask error enhance factor (MEEF) satisfying a first threshold (e.g., exceeding the first threshold), a depth of focus (DoF) satisfying a second threshold (e.g., below the second threshold), a normalized image log-slope (NILS) satisfying a third threshold (e.g., below the third threshold), or other such criterion, may be considered as a critical feature. In some embodiments, a user may specify a target feature as a critical feature. Accordingly, the distance map component 650 may generate a distance modulation map in which the locations of the map are weighted based on their proximity to the critical feature. That is, locations closer to the critical features are assigned greater weight than the locations farther from the critical features. The weighting component 675 may process the error cluster map 406 and the distance modulation map, as described above, to adjust the evaluation result of the error cluster 408 based on its distance or proximity to the critical features.

While the foregoing description discusses determining the evaluation result of a single error cluster, the evaluation result of various such error clusters in the error cluster map 406 may be determined similarly. Thereafter, an evaluation result (e.g., a rank or an overall score) of the predicted image 312a or the simulation model 350a that generated the predicted image 312a may be determined as a function of the evaluation results (e.g., scores) of the various error clusters. The evaluation results of other predicted images 312b-312n (or simulation models 350b-350n) may be determined similarly.

The simulation models 350a-350n may be evaluated (e.g., ranked) based on their evaluation results (e.g., overall scores or scores of error clusters) to select a specific simulation model that satisfies selection criteria. The selected simulation model may then be used to generate predicted images for various target patterns that may be used to generate mask patterns, which may further be used in a patterning process to print patterns on the substrate. Various selection criteria may be defined for the selection of the simulation models. For example, a simulation model with the highest rank (e.g., lowest overall score) may be selected. In another example, a simulation model which has the lowest number of error clusters associated with scores exceeding a specified threshold may be selected. In another example, a simulation model which has an error cluster associated with a score exceeding a specified threshold may not be selected.

While scoring and evaluating the simulation models is one application of identifying the error clusters, another application may include outputting information related to error clusters and their location data in a graphical user interface (GUI). For example, the system 400 may display a predicted image with information regarding the location of error clusters in the predicted image (e.g., by highlighting a portion, location or region of the predicted image 312a having errors corresponding to the error cluster 408). The location information may help the user in manually reviewing the errors in the predicted image at the identified location. Another application of identification of error clusters and their location information includes feeding the information regarding error clusters back to the simulation models to train or adjust the simulation models to improve the prediction of images in those poor prediction areas (e.g., regions of predicted images having error clusters).

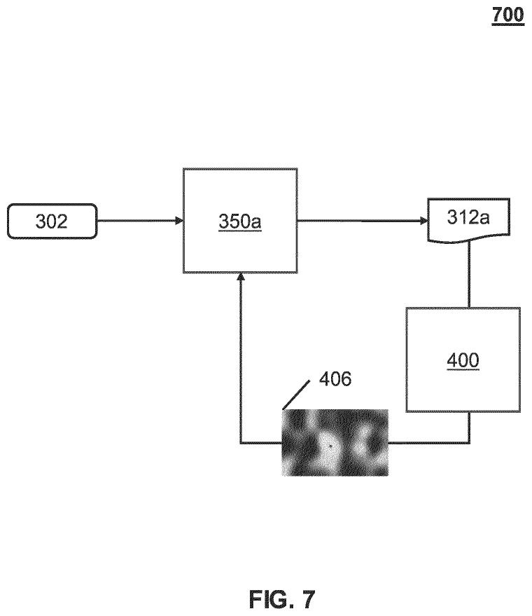

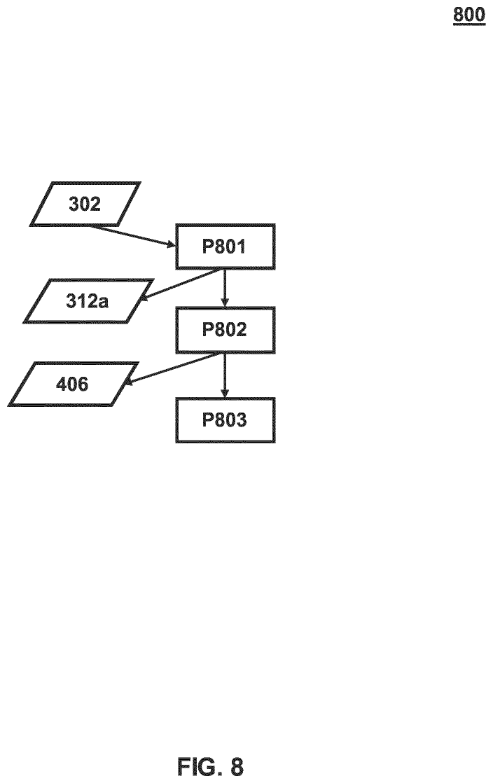

The following description illustrates training of a simulation model 350a based on error cluster map 406 at least with reference to FIGS. 7 and 8. FIG. 7 is a block diagram of a system 700 for training a simulation model to generate a pattern representation (e.g., a predicted image) based on cluster error data (e.g., an error cluster map), in accordance with one or more embodiments. FIG. 8 is a flow chart of a process 800 of training a simulation model to generate a pattern representation (e.g., a predicted image based) on cluster error data (e.g., an error cluster map), in accordance with one or more embodiments. In some embodiments, the simulation model 350a is considered to be “partially” trained simulation model, which is trained to generate a predicted image for a given input image. For example, the simulation model 350a may be trained to generate a predicted image 312a for a given target image 302. The training data may include (a) a set of target images having target patterns and (b) reference images having intermediate patterns corresponding to the target patterns. The predicted images generated by the partially trained simulation model 350a may however, have errors such as those represented by the error cluster map 406. The simulation model 350a may be further trained or adjusted (e.g., “fully” trained) by feeding the error cluster information (e.g., error cluster map 406 and location information of the error cluster 408 in the predicted image312a) back to the simulation model 350a to generate an adjusted predicted image (e.g., predicted image 312a with an improved prediction such that the number of errors in the location of the error cluster 408 is minimized).

In an operation P801, a predicted image, such as a predicted image 312a is obtained. For example, the predicted image 312a is obtained by executing the simulation model 350a with an input image, such as a target image 302, as input. As described above, the target image 302 may include a target pattern to be printed on a substrate, and the predicted image 312a may include intermediate patterns that may be used to generate a mask pattern that may further be used to print patterns corresponding to the target pattern on the substrate via a patterning process.

In an operation P802, cluster error data is derived from the predicted image by the system 400. In some embodiments, the cluster error data may include an error cluster map that is representative of error clusters in the predicted image. An error cluster is indicative of a collection of errors in a specified location or region of the predicted image that satisfies a threshold value. The error cluster map may be derived from the predicted image in a number of ways. For example, the system 400 may generate a prediction error map 404, which indicative of errors in the predicted image 312a (e.g., compared to a reference image 402), and derive the error cluster map 406 from the prediction error map 404, as described at least with reference to FIG. 4. In some embodiments, the presence of an error cluster may impact the patterns printed on the substrate. Accordingly, eliminating the error clusters may minimize the errors in the patterns printed on the substrate. The error clusters may be eliminated by feeding the error cluster information to the simulation model 350a and training the simulation model 350a to improve the prediction in the areas having those error clusters.

In an operation P808, the cluster error data such as the error cluster map 406 having the error cluster 408, and location of the error cluster 408 in the predicted image 312a are input to the simulation model 350a for further training the simulation model 350a to generate an adjusted predicted image.

As part of the training process, a cost function of the simulation model 350a that is indicative of a difference between the predicted image and the reference image (e.g., reference image 402 that is input as part of training data) is determined. The parameters of the simulation model 350a (e.g., weights or biases of the machine learning model) are adjusted such that the cost function is reduced. The parameters may be adjusted in various ways. For example, the parameters may be adjusted based on a gradient descent method. Then, a determination is made as to whether a training condition is satisfied. If the training condition is not satisfied, the training process is executed again with the same images (e.g., target image 302, predicted image 312a, reference image 402, error cluster map 406) or another set of images (e.g., target image 302, adjusted predicted image, reference image 402, new error cluster map) iteratively until the training condition is satisfied. The training condition may be satisfied when the cost function is minimized, the rate at which the cost function reduces is below a threshold value, the training process is executed for a predefined number of iterations, or other such condition. The training process may conclude when the training condition is satisfied. At the end of the training process (e.g., when the training condition is satisfied), the simulation model 350a may be used as a “fully” trained simulation model 350a, and may be used to predict an image having intermediate patterns for any target image.

While the foregoing paragraphs describe the methods and systems with reference to images in the context of lithography, they may be implemented for images in other applications as well. The methods and systems may be implemented for finding error clusters in, or evaluating or training simulation models that generate, other types of images (e.g., images of animals, humans, buildings, objects, or other entities). For example, the simulation model 350a may be configured to predict an image of human from a sketch or outline of the human. The system 400 may be configured to find error clusters in the predicted image of the human (e.g., derived from a prediction error map that is generated by comparing the predicted image and a reference image of the human), score the predicted image based on the error clusters, or adjust the simulation model 350 by feeding back the error cluster to the simulation model 350a to generate an adjusted predicted image of the human.

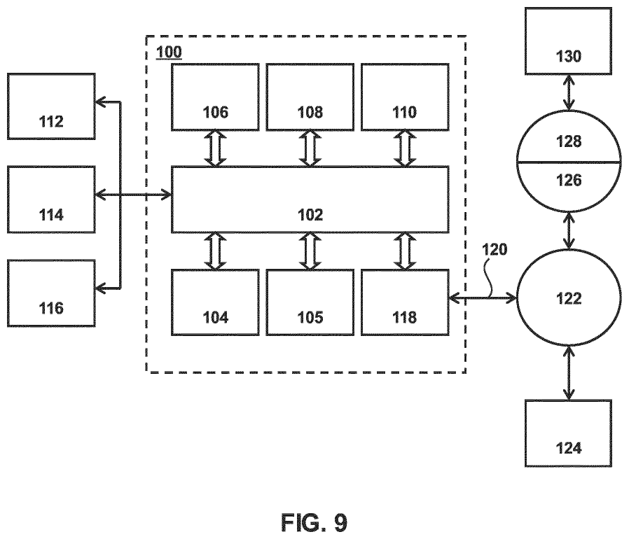

FIG. 9 is a block diagram that illustrates a computer system 100 which can assist in implementing the systems and methods disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

Embodiments of the present disclosure can be further described by the following clauses.

1. A non-transitory computer-readable medium having instructions that, when executed by a computer, cause the computer to execute a method for determining error clusters in a predicted pattern representation and using location information of the error clusters as an input for training a machine learning model to generate an adjusted predicted pattern representation for use in printing a target pattern on a substrate, the method comprising: obtaining, using a first machine learning model, a first predicted pattern representation associated with a target pattern to be printed on a substrate;
obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and
training, based on location information of the first plurality of error clusters, the first machine learning model to generate an adjusted predicted pattern representation.

2. The computer-readable medium of clause 1, wherein obtaining the cluster error data includes: obtaining a prediction error map from the first predicted pattern representation, the prediction error map indicative of a plurality of errors in the first predicted pattern representation compared to a reference pattern representation.

3. The computer-readable medium of clause 2, wherein the prediction error map comprises a difference between each pixel in the first predicted pattern representation and a corresponding pixel in the reference pattern representation.

4. The computer-readable medium of clause 2, wherein the reference pattern representation includes an intermediate pattern that is used generating a mask pattern, which is further used in printing the target pattern on the substrate.

5. The computer-readable medium of clause 2, wherein obtaining the cluster error data includes:
clustering the errors in the prediction error map to generate the first plurality of error clusters.

6. The computer-readable medium of clause 5, wherein clustering the errors includes:
performing a linear transformation on the prediction error map to derive the first plurality of error clusters.

7. The computer-readable medium of clause 6, wherein performing the linear transformation includes:
performing a convolution operation on the prediction error map to derive the cluster error data.

8. The computer-readable medium of clause 5, wherein clustering the errors includes:
performing a non-linear transformation on the prediction error map to derive the cluster error data.

9. The computer-readable medium of clause 5 further comprising:
evaluating the first plurality of error clusters to generate an evaluation result, wherein the evaluation result includes a score for an error cluster, wherein the score is representative of a degree of error caused in printing the target pattern on the substrate using the first predicted pattern representation.

10. The computer-readable medium of clause 9, wherein obtaining the cluster error data includes determining one of the first plurality of error clusters associated with a score satisfying a score threshold as the first error cluster.

11. The computer-readable medium of clause 9, wherein the score is determined as a function of local maxima of the error cluster.

12. The computer-readable medium of clause 9, wherein the score is determined as a function of pixel errors in the error cluster.

13. The computer-readable medium of clause 9 further comprising:
determining the evaluation result of the error cluster further based on a distance of the error cluster in the first predicted pattern representation to patterns corresponding to target features of the target pattern.

14. The computer-readable medium of clause 13, wherein determining the evaluation result further based on a distance of the error cluster includes:
increasing the score as the distance between the error cluster and the target features decreases.

15. The computer-readable medium of clause 13 further comprising:
determining the evaluation result of the error cluster further based on a distance of the error cluster in the first predicted pattern representation to a pattern corresponding to a target feature that satisfies a specified criterion.

16. The computer-readable medium of clause 13, wherein determining the evaluation result includes:
obtaining a target pattern representation associated with the target pattern, the target pattern representation including the target features associated with the target pattern;
extracting edges of the target features;
generating a distance modulation map using the edges of the target features, wherein the distance modulation map assigns weight to different locations in the distance modulation map based on the distance of the locations from the target features; and
processing the cluster error data and the distance modulation map to obtain the evaluation result of the error cluster based on the distance of the error cluster to patterns corresponding to the target features.

17. The computer-readable medium of clause 5, wherein clustering the errors includes:
clustering, based on a specified number of dimensions of the predicted pattern representation, locations of pixels in the predicted error map having errors.

18. The computer-readable medium of clause 1 further comprising:
obtaining a first evaluation result associated with the first predicted pattern representation, the first evaluation result including a first set of scores determined based on the first plurality of error clusters;
obtaining, using a second machine learning model, a second predicted pattern representation associated with the target pattern;
obtaining a second evaluation result associated with the second predicted pattern representation, the second evaluation result including a second set of scores determined based on a second plurality of error clusters associated with the second predicted pattern representation; and
evaluating the first machine learning model and the second machine learning model based on the first evaluation result and the second evaluation result.

19. The computer-readable medium of clause 18 further comprising:
using one of the first predicted pattern representation or the second predicted pattern representation in printing the target pattern on the substrate based on the evaluating.

20. The computer-readable medium of clause 1 further comprising:
generating a mask pattern based on the adjusted predicted pattern representation.

21. The computer-readable medium of clause 20 further comprising:
performing a patterning step using the mask pattern to print patterns corresponding to the target pattern on the substrate via a lithographic process.

22. The computer-readable medium of clause 1, wherein obtaining the first predicted pattern representation includes:
inputting a target pattern representation associated with the target pattern to the first machine learning model.

23. The computer-readable medium of clause 1, wherein the cluster error data includes an error cluster map that is indicative of the first plurality of error clusters.

24. The computer-readable medium of clause 1, wherein the first predicted pattern representation includes a first image, and wherein the adjusted predicted pattern representation includes a second image.

25. A non-transitory computer-readable medium having instructions that, when executed by a computer, cause the computer to execute a method for determining error clusters in a predicted pattern representation and using location information of the error clusters, the method comprising:
obtaining, using a machine learning model, a first predicted pattern representation associated with a target pattern to be printed on a substrate;
obtaining a prediction error map from the first predicted pattern representation, the prediction error map indicative of a plurality of errors in the first predicted pattern representation compared to a reference pattern representation;
obtaining cluster error data from the prediction error map, wherein the cluster error data is indicative of a first plurality of error clusters, the first plurality of error clusters including a first error cluster that is indicative of a collection of errors in a specified region in the first predicted pattern representation; and
generating for display, on a user interface, the cluster error data.

26. The computer-readable medium of clause 25, wherein the prediction error map comprises a difference between each pixel in the first predicted pattern representation and a corresponding pixel in the reference pattern representation.

27. The computer-readable medium of clause 25, wherein the reference pattern representation includes an intermediate pattern that is used generating a mask pattern, which is further used in printing the target pattern on the substrate.

28. The computer-readable medium of clause 25, wherein obtaining the cluster error data includes:
clustering the errors in the prediction error map to generate the first plurality of error clusters.

29. The computer-readable medium of clause 28, wherein clustering the errors includes:
performing a linear transformation on the prediction error map to derive the first plurality of error clusters.

30. The computer-readable medium of clause 29, wherein performing the linear transformation includes:
performing a convolution operation on the prediction error map to derive the cluster error data.

31. The computer-readable medium of clause 28, wherein clustering the errors includes:
performing a non-linear transformation on the prediction error map to derive the cluster error data.

32. The computer-readable medium of clause 28 further comprising:
evaluating the first plurality of error clusters to generate an evaluation result, wherein the evaluation result includes a score for an error cluster, wherein the score is representative of a degree of error caused in printing the target pattern on the substrate using the first predicted pattern representation.

33. The computer-readable medium of clause 32 further comprising:
determining the evaluation result of the error cluster further based on a distance of the error cluster in the first predicted pattern representation to patterns corresponding to target features of the target pattern.

34. The computer-readable medium of clause 33, wherein determining the evaluation result further based on a distance of the error cluster includes:
increasing the score as the distance between the error cluster and the target features decreases.

35. The computer-readable medium of clause 25 further comprising:
training, based on location information of the first plurality of error clusters, the first machine learning model to generate an adjusted predicted pattern representation.

36. The computer-readable medium of clause 25 further comprising:
obtaining a first set of scores associated with the first predicted pattern representation, the first set of scores determined based on the first plurality of error clusters;
obtaining, using a second machine learning model, a second predicted pattern representation associated with the target pattern;
obtaining a second set of scores associated with the second predicted pattern representation, the second set of scores determined based on a second plurality of error clusters associated with the second predicted pattern representation; and
evaluating the first machine learning model and the second machine learning model based on the first set of scores and the second set of scores.

37. The computer-readable medium of clause 36 further comprising:
using one of the first predicted pattern representation or the second predicted pattern representation in printing the target pattern on the substrate based on the evaluating.

38. The computer-readable medium of clause 25, wherein the cluster error data includes an error cluster map that is indicative of the first plurality of error clusters.

39. The computer-readable medium of clause 25, wherein the first predicted pattern representation includes an image.

40. A non-transitory computer-readable medium having instructions that, when executed by a computer, cause the computer to execute a method for selecting a machine learning model among a plurality of machine learning models for generating a predicted image to be used in printing a target pattern on a substrate, the method comprising:
obtaining, using a plurality of machine learning models, a plurality of predicted images associated with a target pattern to be printed on a substrate, wherein the predicted images include a first predicted image generated using a first machine learning model of the plurality of machine learning models;
obtaining a plurality of scores associated with the predicted images, the plurality of scores including a first score associated with the first predicted image, wherein the first score is determined based on a first plurality of prediction errors in the first predicted image;
evaluating the machine learning models based on the scores; and
selecting the first machine learning model based on the first score satisfying a specified criterion.

41. The computer-readable medium of clause 40 further comprising:
inputting a specified target image associated with a specified target pattern to the first machine learning model; and
executing the first machine learning model to generate a specified predicted image associated with the specified target pattern.

42. The computer-readable medium of clause 41 further comprising:
generating a mask pattern based on the specified predicted image.

43. The computer-readable medium of clause 42 further comprising:
performing a patterning step using the mask pattern to print patterns corresponding to the specified target pattern on the substrate via a lithographic process.

44. The computer-readable medium of clause 40, wherein obtaining the plurality of scores includes:
generating a prediction error map, the prediction error map indicative of a plurality of errors in the first predicted image compared to a reference image.

45. The computer-readable medium of clause 44, wherein the prediction error map comprises a difference between each pixel in the first predicted image and a corresponding pixel in the reference image.

46. The computer-readable medium of clause 44, wherein the reference image includes an intermediate pattern that is used generating a mask pattern, which is further used in printing the target pattern on the substrate.

47. The computer-readable medium of clause 44, wherein obtaining the plurality of scores includes:
clustering the errors in the prediction error map to generate a first plurality of error clusters, the first plurality of error clusters including a first error cluster that is indicative of a collection of errors in a specified location in the first predicted image.

48. The computer-readable medium of clause 47 further comprising:
determining a set of scores of the first plurality of error clusters as the first score, wherein the set of scores includes a score of the first error cluster, the score representative of a degree of error caused in printing the target pattern on the substrate using the first predicted image.

49. The computer-readable medium of clause 48, wherein the score is determined as a function of local maxima of the first error cluster.

50. The computer-readable medium of clause 48, wherein the score is determined as a function of pixel errors in the first error cluster.

51. The computer-readable medium of clause 48 further comprising:
adjusting the score of the first error cluster based on a distance of the first error cluster in the first predicted image to patterns corresponding to target features of the target pattern.

52. The computer-readable medium of clause 51 further comprising:
adjusting the score of the first error cluster based on a distance of the first error cluster in the first predicted image to a critical feature, the critical feature including a target feature that satisfies a specified criterion.

53. The computer-readable medium of clause 47, wherein clustering the errors includes:
performing a linear transformation on the prediction error map to derive the first plurality of error clusters.

54. The computer-readable medium of clause 6, wherein performing the linear transformation includes:
performing a convolution operation on the prediction error map to derive the cluster error data.

55. A method for determining error clusters in a predicted pattern representation and using location information of the error clusters as an input for training a machine learning model to generate an adjusted predicted pattern representation for use in printing a target pattern on a substrate, the method comprising:
obtaining, using a first machine learning model, a first predicted pattern representation associated with a target pattern to be printed on a substrate;
obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and
training, based on location information of the first plurality of error clusters, the first machine learning model to generate an adjusted predicted pattern representation.

56. A method for determining error clusters in a predicted pattern representation and using location information of the error clusters, the method comprising:
obtaining, using a machine learning model, a first predicted pattern representation associated with a target pattern to be printed on a substrate;
obtaining a prediction error map from the first predicted pattern representation, the prediction error map indicative of a plurality of errors in the first predicted pattern representation compared to a reference pattern representation;
obtaining cluster error data from the prediction error map, wherein the cluster error data is indicative of a first plurality of error clusters, the first plurality of error clusters including a first error cluster that is indicative of a collection of errors in a specified region in the first predicted pattern representation; and
generating for display, on a user interface, the cluster error data.

57. A method for selecting a machine learning model among a plurality of machine learning models for generating a predicted image to be used in printing a target pattern on a substrate, the method comprising:
obtaining, using a plurality of machine learning models, a plurality of predicted images associated with a target pattern to be printed on a substrate, wherein the predicted images include a first predicted image generated using a first machine learning model of the plurality of machine learning models;
obtaining a plurality of scores associated with the predicted images, the plurality of scores including a first score associated with the first predicted image, wherein the first score is determined based on a first plurality of prediction errors in the first predicted image;
evaluating the machine learning models based on the scores; and
selecting the first machine learning model based on the first score satisfying a specified criterion.

58. An apparatus for determining error clusters in a predicted pattern representation and using location information of the error clusters as an input for training a machine learning model to generate an adjusted predicted pattern representation for use in printing a target pattern on a substrate, the apparatus comprising:
a memory storing a set of instructions; and
a processor configured to execute the set of instructions to cause the apparatus to perform a method of:
   obtaining, using a first machine learning model, a first predicted pattern representation associated with a target pattern to be printed on a substrate;
   obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and
   training, based on location information of the first plurality of error clusters, the first machine learning model to generate an adjusted predicted pattern representation.

59. An apparatus for determining error clusters in a predicted pattern representation and using location information of the error clusters, the apparatus comprising:
a memory storing a set of instructions; and
a processor configured to execute the set of instructions to cause the apparatus to perform a method of:
   obtaining, using a machine learning model, a first predicted pattern representation associated with a target pattern to be printed on a substrate;
   obtaining a prediction error map from the first predicted pattern representation, the prediction error map indicative of a plurality of errors in the first predicted pattern representation compared to a reference pattern representation;
   obtaining cluster error data from the prediction error map, wherein the cluster error data is indicative of a first plurality of error clusters, the first plurality of error clusters including a first error cluster that is indicative of a collection of errors in a specified region in the first predicted pattern representation; and
   generating for display, on a user interface, the cluster error data.

60. An apparatus for selecting a machine learning model among a plurality of machine learning models for generating a predicted image to be used in printing a target pattern on a substrate, the apparatus comprising:
a memory storing a set of instructions; and
a processor configured to execute the set of instructions to cause the apparatus to perform a method of:
   obtaining, using a plurality of machine learning models, a plurality of predicted images associated with a target pattern to be printed on a substrate, wherein the predicted images include a first predicted image generated using a first machine learning model of the plurality of machine learning models;
   obtaining a plurality of scores associated with the predicted images, the plurality of scores including a first score associated with the first predicted image, wherein the first score is determined based on a first plurality of prediction errors in the first predicted image;
   evaluating the machine learning models based on the scores; and
   selecting the first machine learning model based on the first score satisfying a specified criterion.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A method comprising:
obtaining, using a first machine learning model, a first predicted pattern representation associated with a target pattern to be printed on a substrate;
obtaining cluster error data from the first predicted pattern representation, wherein the cluster error data is indicative of a first plurality of error clusters, the first plurality of error clusters including a first error cluster that is indicative of a collection of errors in a specified region in the first predicted pattern representation; and
training, based on location information of the first plurality of error clusters, the first machine learning model to generate an adjusted predicted pattern representation.

2. The method of claim 1, wherein obtaining the cluster error data includes obtaining a prediction error map from the first predicted pattern representation, the prediction error map indicative of a plurality of errors in the first predicted pattern representation compared to a reference pattern representation.

3. The method of claim 2, wherein the prediction error map comprises a difference between each pixel in the first predicted pattern representation and a corresponding pixel in the reference pattern representation.

4.-13. (canceled)

14. The method of claim 1, further comprising:
obtaining a first evaluation result associated with the first predicted pattern representation, the first evaluation result including a first set of scores determined based on the first plurality of error clusters;
obtaining, using a second machine learning model, a second predicted pattern representation associated with the target pattern;
obtaining a second evaluation result associated with the second predicted pattern representation, the second evaluation result including a second set of scores determined based on a second plurality of error clusters associated with the second predicted pattern representation; and
evaluating the first machine learning model and the second machine learning model based on the first evaluation result and the second evaluation result.

15. The method of claim 1, further comprising generating a mask pattern based on the adjusted predicted pattern representation.

16.-18. (canceled)

19. A non-transitory computer-readable medium having stored instructions that, when executed by a computer system, are configured to cause the computer system to at least:
obtain, using a first machine learning model, a first predicted pattern representation associated with a target pattern to be printed on a substrate;
obtain cluster error data from the first predicted pattern representation, wherein the cluster error data is indicative of a first plurality of error clusters, the first plurality of error clusters including a first error cluster that is indicative of a collection of errors in a specified region in the first predicted pattern representation; and
train, based on location information of the first plurality of error clusters, the first machine learning model to generate an adjusted predicted pattern representation.

20. The medium of claim 19, wherein the instructions configured to cause the computer system to obtain the cluster error data are further configured to cause the computer system to obtain a prediction error map from the first predicted pattern representation, the prediction error map indicative of a plurality of errors in the first predicted pattern representation compared to a reference pattern representation.

21. The medium of claim 20, wherein the prediction error map comprises a difference between each pixel in the first predicted pattern representation and a corresponding pixel in the reference pattern representation.

22. The medium of claim 20, wherein the reference pattern representation includes an intermediate pattern that is used to generate a mask pattern, which mask pattern is used in printing the target pattern on the substrate.

23. The medium of claim 20, wherein the instructions configured to cause the computer system to obtain the cluster error data are further configured to cause the computer system to cluster the errors in the prediction error map to generate the first plurality of error clusters.

24. The medium of claim 23, wherein the instructions configured to cause the computer system to cluster the errors are further configured to cause the computer system to perform a transformation on the prediction error map to derive the first plurality of error clusters.

25. The medium of claim 23, wherein the instructions are further configured to cause the computer system to evaluate the first plurality of error clusters to generate an evaluation result indicating a degree of error caused in printing of the target pattern on the substrate using the first predicted pattern representation.

26. The medium of claim 25, wherein the evaluation result is determined as a function of pixel errors in the error cluster.

27. The medium of claim 25, wherein the instructions are further configured to cause the computer system to determine the evaluation result of the error cluster further based on a distance between the error cluster in the first predicted pattern representation and patterns corresponding to target features of the target pattern.

28. The medium of claim 27, wherein the instructions configured to cause the computer system to determine the evaluation result are further configured to cause the computer system to:
obtain a target pattern representation associated with the target pattern, the target pattern representation including the target features associated with the target pattern;
extract edges of the target features;
generate a distance modulation map using the edges of the target features, wherein the distance modulation map assigns weight to different locations in the distance modulation map based on the distance of the locations from the target features; and
process the cluster error data and the distance modulation map to obtain the evaluation result of the error cluster based on the distance of the error cluster to patterns corresponding to the target features.

29. The medium of claim 23, wherein the instructions configured to cause the computer system to cluster the errors are further configured to cause the computer system to cluster, based on a specified number of dimensions of the predicted pattern representation, locations of pixels in the predicted error map having errors.

30. The medium of claim 19, wherein the instructions are further configured to cause the computer system to:
obtain a first evaluation result associated with the first predicted pattern representation, the first evaluation result including a first set of scores determined based on the first plurality of error clusters;
obtain, using a second machine learning model, a second predicted pattern representation associated with the target pattern;
obtain a second evaluation result associated with the second predicted pattern representation, the second evaluation result including a second set of scores determined based on a second plurality of error clusters associated with the second predicted pattern representation; and
evaluate the first machine learning model and the second machine learning model based on the first evaluation result and the second evaluation result.

31. The medium of claim 19, wherein the instructions are further configured to cause the computer system to generate a mask pattern based on the adjusted predicted pattern representation.

32. The medium of claim 19, wherein the instructions configured to cause the computer system to obtain the first predicted pattern representation are further configured to cause the computer system to input a target pattern representation associated with the target pattern to the first machine learning model.

33. The medium of claim 19, wherein the cluster error data includes an error cluster map that is indicative of the first plurality of error clusters.
